(19) United States
(12) Patent Application Publication
(10) Pub. No.: US 2025/0377221 A1
(43) Pub. Date: Dec. 11, 2025

(54) METHOD FOR STRAIGHTENING THE MAGNETIC FIELD OF A MAGNET AND A POSITION SENSOR INCORPORATING THE MAGNET

(71) Applicant: HONEYWELL INTERNATIONAL INC., Charlotte, NC (US)

(72) Inventors: Petr Cizek, Brno (CZ); Michal Jasansky, Brno (CZ); Tomas Ripel, Brno (CZ); Miroslav Zemanek, Brno (CZ)

(73) Assignee: HONEYWELL INTERNATIONAL INC., Charlotte, NC (US)

(21) Appl. No.: 18/739,561

(22) Filed: Jun. 11, 2024

(51) Int. Cl. G01D 5/14; G01R 33/07

(52) U.S. Cl. CPC G01D 5/145; G01R 33/07

(57) ABSTRACT

A sensor includes a Hall sensor and a magnet assembly. The magnet assembly is disposed a first predetermined distance from the Hall sensor and includes a magnet and a ferromagnetic structure. the magnet has an outer peripheral surface and a flat end face that is disposed perpendicular to an axis that extends through a center of the flat end face. The ferromagnetic structure has an inner peripheral surface and surrounds the magnet and extends, toward the Hall sensor, a second predetermined distance beyond the flat end face. The magnet exhibits a first variation in magnetic field orientation at least at the first predetermined distance from the flat end face, the magnet assembly exhibits a second variation in magnetic field orientation at least at the first predetermined distance from the flat end face, and the first variation in magnetic field orientation is greater than the second variation in magnetic field orientation.

### TECHNICAL FIELD

The present disclosure generally relates to sensors and sensor systems that include a magnet and, more particularly, to a method for straightening the magnetic field of magnets used in such sensors and sensing systems.

### BACKGROUND

Hall sensors are used in myriad systems to detect the rotational position of various devices. As is generally known, a Hall sensor is used to measure x and y components of magnetic flux density and consequently to determine the angle of magnet rotation. The precision of Hall sensors can vary depending on the shape of magnetic field. A generally straight, homogeneous magnetic field is desirable for improved precision. However, this cannot always be achieved.

Hence, there is a need for a method of straightening the magnetic field of magnets used in in conjunction with Hall sensors. The present disclosure addresses at least this need.

### BRIEF SUMMARY

This summary is provided to describe select concepts in a simplified form that are further described in the Detailed Description. This summary is not intended to identify key or essential features of the claimed subject matter, nor is it intended to be used as an aid in determining the scope of the claimed subject matter.

In one embodiment, a sensor includes a Hall sensor and a magnet assembly. The magnet assembly is disposed a first predetermined distance from the Hall sensor and includes a magnet and a ferromagnetic structure. the magnet has an outer peripheral surface and a flat end face that is disposed perpendicular to an axis that extends through a center of the flat end face. The ferromagnetic structure has an inner peripheral surface and surrounds the magnet and extends, toward the Hall sensor, a second predetermined distance beyond the flat end face. The magnet exhibits a first variation in magnetic field orientation at least at the first predetermined distance from the flat end face. The magnet assembly exhibits a second variation in magnetic field orientation at least at the first predetermined distance from the flat end face. And the first variation in magnetic field orientation is greater than the second variation in magnetic field orientation.

In another embodiment, a sensor system for sensing the rotational position of a rotatable component that is rotatable about a rotational axis includes a Hall sensor and a magnet assembly. The magnet assembly is disposed on the rotatable component and at a first predetermined distance from the Hall sensor. The magnet assembly includes a magnet and a ferromagnetic structure. The magnet has an outer peripheral surface and a flat end face that is disposed perpendicular to the rotational axis, which extends through a center of the flat end face. The ferromagnetic structure has an inner peripheral surface surrounds the magnet and extends, toward the Hall sensor, a second predetermined distance beyond the flat end face. The magnet exhibits a first variation in magnetic field orientation at least at the first predetermined distance from the flat end face. The magnet assembly exhibits a second variation in magnetic field orientation at least at the first predetermined distance from the flat end face. And the first variation in magnetic field orientation is greater than the second variation in magnetic field orientation.

In yet another embodiment, a method for straightening the magnetic field of a magnet assembly includes providing a magnet having an outer peripheral surface and a flat end face, where the flat end face is disposed perpendicular to an axis that extends through a center of the flat end face. Providing a ferromagnetic structure having an inner peripheral surface, and surrounding the magnet with the ferromagnetic structure such that the ferromagnetic structure (i) is fixedly mounted relative to the magnet and (ii) extends a first predetermined distance beyond the flat end face, to thereby produce a magnet assembly. The magnet exhibits a first variation in magnetic field orientation at the flat end face, the magnet assembly exhibits a second variation in magnetic field orientation at the flat end face, and the first variation in magnetic field orientation is greater than the second variation in magnetic field orientation.

Furthermore, other desirable features and characteristics of the sensor, sensor system, and method will become apparent from the subsequent detailed description and the appended claims, taken in conjunction with the accompanying drawings and the preceding background.

### BRIEF DESCRIPTION OF DRAWINGS

The present disclosure will hereinafter be described in conjunction with the following drawing figures, wherein like numerals denote like elements, and wherein:

FIG. 1 depicts a simplified representation of one embodiment of a sensor system;

FIG. 2 depicts an end view of one embodiment of a magnet assembly that may be used to implement the sensor system of FIG. 1;

FIG. 3 is a cross section view of the magnet assembly taken along line 3-3 in FIG. 2;

FIG. 4 depicts an end view of another embodiment of a magnet assembly that may be used to implement the sensor system of FIG. 1;

FIG. 5 depicts a method, in flowchart form, for flattening the magnetic field of a magnet;

FIGS. 6 and 7 depict the magnetic density measured near the flat end face of the magnet and the magnet assembly, respectively; and

FIGS. 7 and 8 depict variations of the magnetic field orientation near the flat end face of the magnet and the magnet assembly, respectively.

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

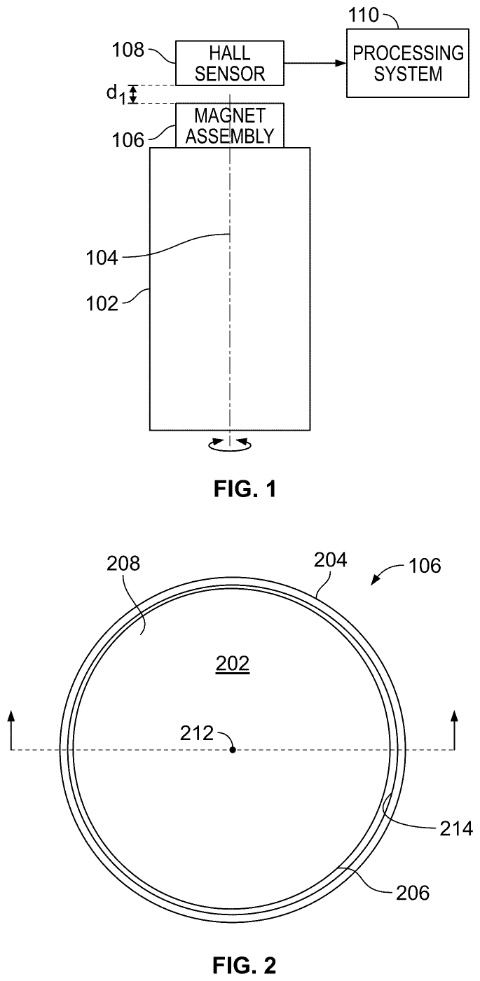

Referring to FIG. 1, a simplified representation of one embodiment of a sensor system 100 is depicted. The sensor system 100, at least in the depicted embodiment, is configured to sense the rotational position of a rotatable component 102. The rotatable component 102 may be, for example, a motor shaft, an actuator shaft, a valve shaft, or any one of numerous other rotatable components. Regardless of the specific end-use of the rotatable component 102, it is rotatable about a rotational axis 104.

The sensor system 100 includes a magnet assembly 106, a Hall sensor 108, and a processing circuit 110. The magnet assembly 106 is disposed on the rotatable component 102. The magnet assembly 106 thus rotates with the rotatable component 102, about the rotational axis 104, whenever the rotatable component 102 rotates. The Hall sensor 108, which may be implemented using one or more Hall elements, is disposed a predetermined distance (d₁) from the magnet assembly 106 and is configured to generate a sensor signal proportional to the axial component of the magnetic field vector supplied from the magnet assembly 106. Although the predetermined distance may vary, in one embodiment the predetermined distance is about 2 mm. No matter the specific distance, the sensor signal is supplied to the processing circuit 110.

The processing circuit 110 is coupled to receive the sensor signal from the Hall sensor 108. The processing circuit 110 is configured to process the sensor signal to thereby determine the rotational position of the rotatable component 102. It will be appreciated that the processing circuit 110 may be part of a controller or other system that may be used to control the rotational position of the rotatable component 102 based on the rotational position determined by the processing system 110.

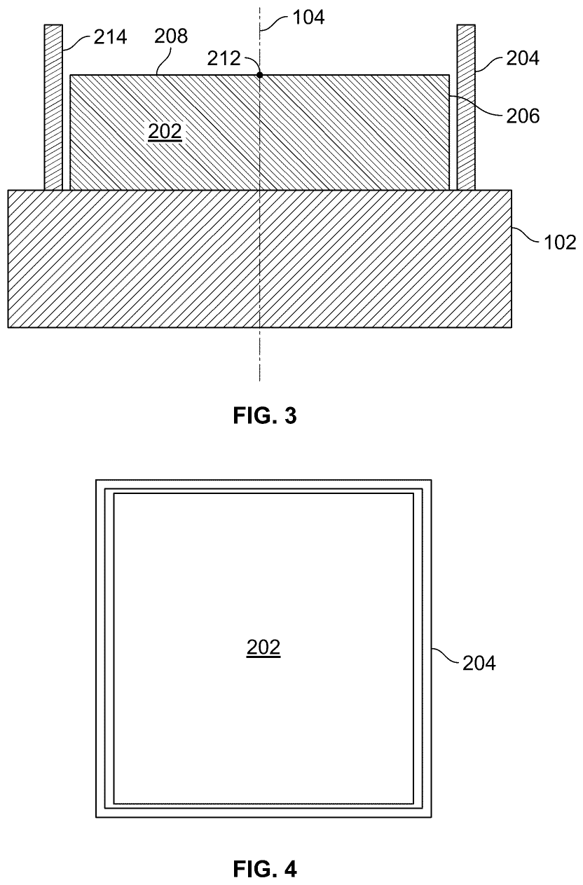

The magnet assembly 106, an embodiment of which is depicted in FIGS. 2 and 3, includes a magnet 202 and a ferromagnetic structure 204. The magnet 202 has an outer peripheral surface 206 and a flat end face 208. As shown most clearly in FIG. 3, when the magnet assembly 106 is disposed on the rotatable component 102, the flat end face 208 of the magnet 106 is disposed perpendicular to the rotational axis 104, and the rotational axis 104 extends through the center 212 of the flat end face 208.

The ferromagnetic structure 204, which may comprise any one of numerous ferromagnetic materials, has an inner peripheral surface 214 and surrounds the magnet 202. In some embodiments, such as the one depicted in FIGS. 2 and 3 depict, the inner peripheral surface 214 of ferromagnetic structure 204 is spaced apart from the outer peripheral surface 206 of the magnet 202. It will be appreciated, however, that in other embodiments the inner peripheral surface 214 of ferromagnetic structure 204 may contact the outer peripheral surface 206 of the magnet 202. In either case, the magnet 202 and ferromagnetic structure 204 are fixedly mounted relative to each other.

The ferromagnetic structure 204 also extends a predetermined distance (d₂) beyond the flat end face 208 of the magnet 202. It will be appreciated that the predetermined distance (d₂) may vary and may depend, for example, on the area of the flat end face 208 of the magnet 202, the thickness of the magnet 202, the thickness of the ferromagnet structure 204, and the material of the ferromagnet structure 204, just to name a few variables. In one embodiment, in which the area of the flat end face 208 of the magnet 202 is 50 mm², the thickness of the magnet 202 is 4 mm, the thickness of the ferromagnet structure 204 is 1 mm, and the material of the ferromagnet structure 204 is steel, the predetermined distance (d) is about 1 mm.

The structural configuration of the magnet assembly 106 described herein provides distinct advantages. For example, the magnetic density measured at the flat end face 208 of the magnet 106 remains substantially constant from the center 212 to a predetermined radial distance (r) from the center 212. In addition, the vector orientation of the magnetic field remains substantially constant across the flat end face 208 of the magnet 106. These two advantages will be more clearly understood in conjunction with the following, which describes a method for straightening the magnetic field of the magnet 106. Before doing so, however, it is noted that although the magnet assembly 106 depicted in FIGS. 2 and 3 is generally circular in cross section, in other embodiments it could have different cross-sectional shapes. For example, in the embodiment depicted in FIG. 4 the magnet assembly 106 has a square cross-sectional shape.

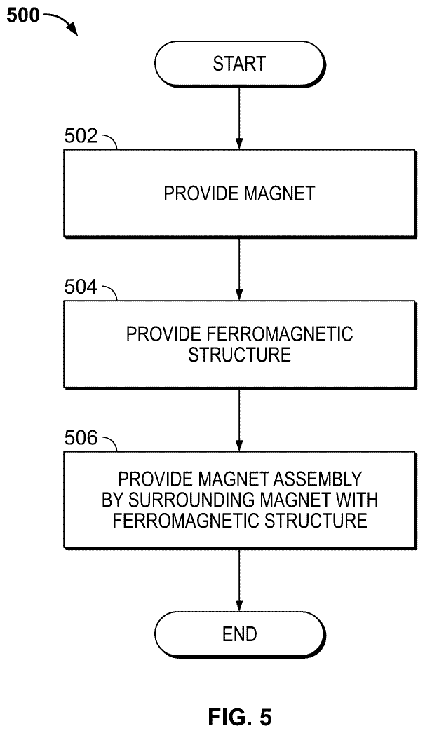

The method 500, which is depicted in flowchart form in FIG. 5, represents various embodiments of a method for flattening the magnetic field of the magnet. For illustrative purposes, the description of method 500 may refer to elements mentioned above in connection with FIGS. 1-4. It should be appreciated that method 500 may include any number of additional or alternative tasks, the tasks shown in FIG. 5 need not be performed in the illustrated order.

The method begins by providing a magnet (502), such as the magnet 202 depicted in FIGS. 1-4, and providing a ferromagnetic structure (504), such as the ferromagnetic structure 204 depicted in FIGS. 1-4. The magnet 202, as previously described, has an outer peripheral surface 206 and a flat end face 208, which is disposed perpendicular to an axis 114 that extends through the center 212 of the flat end face 208. In addition, the ferromagnetic structure 204, as was also previously described, has an inner peripheral surface 214.

Thereafter, the magnet assembly 106 is produced by surrounding the magnet 202 with the ferromagnetic structure 204 (506). More specifically, and as was described above, the ferromagnetic structure 204 surrounds the magnet 202 such that the inner peripheral surface 214 of the ferromagnetic structure 204 is spaced apart from the outer peripheral surface 206 of the magnet 202 or such that at least a portion of the inner peripheral surface 214 of the ferromagnetic structure 204 contacts the outer peripheral surface 206 of the magnet 202. Moreover, the ferromagnetic structure 204 extends the predetermined distance (d₂) beyond the flat end face 208 of the magnet 202.

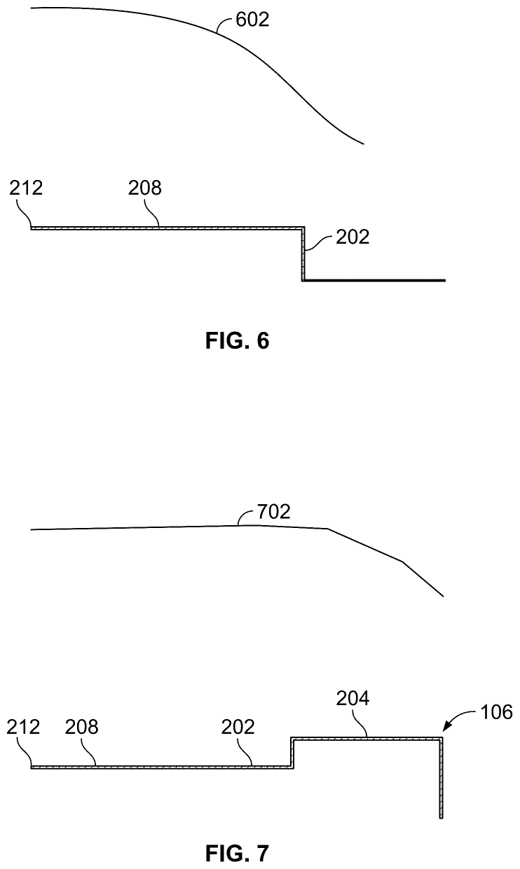

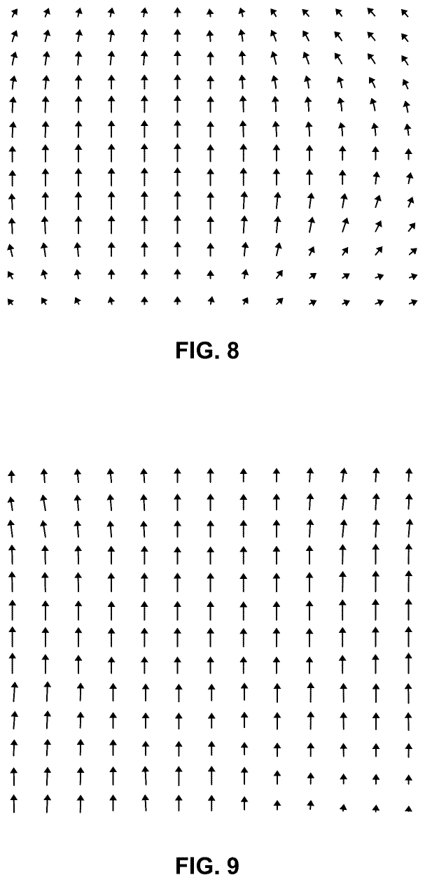

Referring to FIG. 6, the magnetic density measured near the flat end face 212 (e.g., at a distance corresponding to about predetermined distance d₁) of one embodiment of the magnet 202, prior to the magnet 202 being surrounded by the ferromagnetic structure 204, is depicted. As illustrated therein, the magnetic density 602 decreases radially outwardly, in a continuous and non-linear manner, from a first maximum magnitude at the center 212 of the flat end face 208. This can be compared to FIG. 7, which depicts the magnetic density measured at the same distance from the flat end face 212 of the magnet assembly 106. That is, after the same magnet 202 is surrounded by one embodiment of the ferromagnetic structure 204. As depicted in FIG. 7, the magnetic density 702 measured at that distance from the flat end face 208 of the magnet assembly 106 remains substantially constant from the center 212 to the predetermined radial distance (r) from the center 212.

In addition to the above, as FIG. 8 depicts, the magnet 202, prior to being surrounded by the ferromagnetic structure 204, exhibits a first variation in magnetic field orientation across the flat end face 212. Conversely, as FIG. 9 depicts, the magnet assembly 106 exhibits a second variation in magnetic field orientation near the flat end face 212. By comparing FIGS. 8 and 9, it is seen that the first variation in magnetic field orientation is greater than the second variation in magnetic field orientation.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language. The sequence of the text in any of the claims does not imply that process steps must be performed in a temporal or logical order according to such sequence unless it is specifically defined by the language of the claim. The process steps may be interchanged in any order without departing from the scope of the invention as long as such an interchange does not contradict the claim language and is not logically nonsensical.

Furthermore, depending on the context, words such as “connect” or “coupled to” used in describing a relationship between different elements do not imply that a direct physical connection must be made between these elements. For example, two elements may be connected to each other physically, electronically, logically, or in any other manner, through one or more additional elements.

As used herein, the term “substantially” denotes within 5% to account for manufacturing tolerances. Also, as used herein, the term “about” denotes within 5% to account for manufacturing tolerances.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A sensor, comprising:
a Hall sensor; and
a magnet assembly disposed a first predetermined distance from the Hall sensor, the magnet assembly comprising:
a magnet, the magnet having an outer peripheral surface and a flat end face, the flat end face disposed perpendicular to an axis that extends through a center of the flat end face; and
a ferromagnetic structure having an inner peripheral surface, the ferromagnetic structure surrounding the magnet and extending, toward the Hall sensor, a second predetermined distance beyond the flat end face,
wherein:
the magnet exhibits a first variation in magnetic field orientation at least at the first predetermined distance from the flat end face;
the magnet assembly exhibits a second variation in magnetic field orientation at least at the first predetermined distance from the flat end face; and
the first variation in magnetic field orientation is greater than the second variation in magnetic field orientation.

2. The sensor of claim 1, wherein a magnetic density measured at least at the first predetermined distance from the flat end face of the magnet assembly remains substantially constant from the center to a predetermined radial distance from the center.

3. The sensor of claim 1, wherein the flat end face of the magnet is circular.

4. The sensor of claim 1, wherein the flat end face of the magnet is square.

5. The sensor of claim 1, wherein the inner peripheral surface of the ferromagnetic structure is spaced apart from the outer peripheral surface of the magnet.

6. The sensor of claim 1, wherein the inner peripheral surface of the ferromagnetic structure contacts the outer peripheral surface of the magnet.

7. A sensor system for sensing rotational position of a rotatable component that is rotatable about a rotational axis, the sensor system comprising:
a Hall sensor; and
the magnet assembly disposed on the rotatable component and at a first predetermined distance from the Hall sensor, the magnet assembly comprising:
a magnet, the magnet having an outer peripheral surface and a flat end face, the flat end face disposed perpendicular to the rotational axis, the rotational axis extending through a center of the flat end face; and
a ferromagnetic structure having an inner peripheral surface, the ferromagnetic structure surrounding the magnet and extending, toward the Hall sensor, a second predetermined distance beyond the flat end face,
wherein:
the magnet exhibits a first variation in magnetic field orientation at least at the first predetermined distance from the flat end face;
the magnet assembly exhibits a second variation in magnetic field orientation at least at the first predetermined distance from the flat end face; and
the first variation in magnetic field orientation is greater than the second variation in magnetic field orientation.

8. The sensor system of claim 7, further comprising:
a processing circuit coupled to receive a sensor signal from the Hall sensor, the sensor signal indicative of the rotational position of the rotatable component, the processing circuit configured to process the sensor signal to thereby determine the rotational position of the rotatable component.

9. The sensor of claim 7, wherein a magnetic density measured within at least at the first predetermined distance from the flat end face of the magnet assembly remains substantially constant from the center to a predetermined radial distance from the center.

10. The sensor system of claim 7, wherein the flat end face of the magnet is circular.

11. The sensor system of claim 7, wherein the flat end face of the magnet is square.

12. The sensor system of claim 7, wherein the inner peripheral surface of the ferromagnetic structure is spaced apart from the outer peripheral surface of the magnet.

13. The sensor system of claim 7, wherein the inner peripheral surface of the ferromagnetic structure contacts the outer peripheral surface of the magnet.

14. A method for straightening the magnetic field of a magnet, the method comprising the steps of:
providing a magnet, the magnet having an outer peripheral surface and a flat end face, the flat end face disposed perpendicular to an axis that extends through a center of the flat end face;
providing a ferromagnetic structure having an inner peripheral surface; and
surrounding the magnet with the ferromagnetic structure such that the ferromagnetic structure (i) is fixedly mounted relative to the magnet and (ii) extends a first predetermined distance beyond the flat end face, to thereby produce a magnet assembly,
wherein:
the magnet exhibits a first variation in magnetic field orientation at the flat end face,
the magnet assembly exhibits a second variation in magnetic field orientation at the flat end face, and
the first variation in magnetic field orientation is greater than the second variation in magnetic field orientation.

15. The method of claim 14, wherein:
a first magnetic density measured at a second predetermined distance from the flat end face of the magnet decreases radially outwardly, in a continuous and non-linear manner, from a first maximum magnitude at the center, and
a second magnetic density measured at the second predetermined distance from the flat end face of the magnet assembly remains substantially constant from the center to a predetermined radial distance from the center.

16. The method of claim 14, wherein the flat end face of the magnet is circular.

17. The method of claim 14, wherein the flat end face of the magnet is square.

18. The method of claim 14, wherein the inner peripheral surface of the ferromagnetic structure is spaced apart from the outer peripheral surface of the magnet.

19. The method of claim 14, wherein the inner peripheral surface of the ferromagnetic structure contacts the outer peripheral surface of the magnet.
